(19) United States
(12) Patent Application Publication
(10) Pub. No.: US 2010/0025706 A1
(43) Pub. Date: Feb. 4, 2010

(54) NANOPARTICLE BASED INORGANIC BONDING MATERIAL

(75) Inventors: Mihaela-Ioana Popovici, Leuven (BE); Marcus Antonius Verschuuren, Tilburg (NL); Christian Kleynen, Deventer (NL); Jan Graaf, Uden (NL)

Correspondence Address: Philips Intellectual Property and Standards, P.O. Box 3001, Briarcliff Manor, NY, 10510-8001, US

(73) Assignee: KONINKLIJKE PHILIPS ELECTRONICS N.V., Eindhoven (NL)

(21) Appl. No.: 12/376,159

(22) PCT Filed: Aug. 6, 2007
(86) PCT No.: PCT/IB2007/053084

§ 371 Date: May 7, 2009

(30) Foreign Application Priority Data
Aug. 8, 2006 (EP) 06118564.1

(51) Int. Cl. H01L 33/00; H01L 21/50

(52) U.S. Cl. 257/98; 438/27; 257/E21.499; 257/E33.067

(57) ABSTRACT

A method for the production of a light emitting device is provided, comprising providing at least one LED 10 and at least one optical element 13; arranging a bonding material 12, comprising a stable colloidal sol of inorganic metal oxide nanoparticles dispersed in a liquid medium, on a light emitting surface 11 of said at least one LED and/or on a surface of said at least one optical element 13; (c) placing said at least one optical element 13 on the light emitting surface 11 of said at least one LED 10 with said bonding material 12 there between to form at least one assembly; and curing said bonding material to form an inorganic bond.

The bonding material may be cured at temperatures not detrimental to the LED, while the resulting bond is photo-thermally stable.

### FIELD OF THE INVENTION

The present invention relates to a method for producing light emitting devices, as well as light emitting devices obtainable by such methods, and to the use of a stable colloidal sol of metal oxide nanoparticles as a bonding material precursor for bonding optical elements to light emitting diodes.

### BACKGROUND OF THE INVENTION

Light emitting diodes (LEDs) are currently contemplated as light sources for several different lighting applications, and the use of light emitting diodes is expected to grow in the coming years.

A light emitting diode is typically comprised in a package containing the actual LED-chip comprising the active, light producing, layers, and light extraction optics arranged on the LED-chip. The light extraction efficiency between the chips and the optics of the package is a major issue with which LEDs are confronted.

A classical approach in this context involves the use of primary extraction optics, e.g. optical domes provided on the LED-chips, which optical domes extract the light based on their refractive properties. The materials of these optical domes are often based on silicones and polymers (such as PMMA). However, these optical domes have limited photo-thermal stability, which limits the power of the used LED-chips, which in turn limits the lumen power of the light-emitting device.

Another challenge is to have the optics such that they withstand high optical power at elevated temperatures, thus enabling high lumen power light sources by using high power LEDs, which dissipate a lot of heat when in operation.

An approach to solve this is to use inorganic optical elements for the extraction of light from LED chips. The material of such optical elements can for example be polycrystalline ceramic materials or glass. Such inorganic optical elements have much higher photo-thermal stability, which allows light emitting devices with high lumen power and output.

However, high power LEDs may dissipate significant amounts of heat, and the radiation may be intense. In this context, the bond between the LED chip and the extraction optics forms a junction that couples light from the LED chip to the extraction optics and physically binds the extraction optics to the LED chip, and should itself exhibit high photo-thermal stability so that it is not the limiting factor in the light-emitting device, and so that it is able to benefit from the high photo-thermal stability of the inorganic extraction optics.

A complicating factor is that the LED-chips themselves only sustain moderate processing temperatures whilst materials with high photo-thermal stability are inorganic and typically are processed at too high temperature for the LED chips.

Thus there is a need for a light emitting device where the bond between the LED-chip and the extraction optics can withstand the load and stress it is exposed to during operation of the device, and which bond is formed under temperatures that are compliant with the LED chips.

### SUMMARY OF THE INVENTION

It is an object of the present invention to overcome this problem, and to provide a light-emitting device in which the LED-chip is bonded to the extraction optics by a bonding material that exhibits high photo-thermal stability, and which may be formed at temperatures not detrimental to the LED-chip

This and other objects that will be evident from the following description of the invention are achieved by means of a light-emitting device and a method for the manufacture of such a device, according to the appended claims.

Thus, in a first aspect, the present invention relates to a method for the manufacture of a light emitting device, comprising: (a) providing at least one light emitting diode and at least one optical element; (b) arranging a bonding material, comprising a stable colloidal sol of inorganic metal oxide nanoparticles dispersed in a liquid medium, on a light emitting surface of said at least one light emitting diode and/or on a surface of said at least one optical element; (c) placing said at least one optical element on the light emitting surface of said at least one light emitting diode with said bonding material there between to form at least one assembly; and (d) curing said bonding material to form an inorganic bond.

The bond thus formed is an essentially purely inorganic bond between the LED and the optical element. Such an inorganic bond is both photo stable and thermally stable. Further, such bond may be obtained using temperatures that are not detrimental to the LED-chip. The formed bond has high transmission throughout the visible wavelength range. Since the bonding material is a stable sol not comprising any reactive precursors, the shelf life is very long, and high temperatures are not needed in order to obtain a dense layer.

It should be noted that materials used as the bonding material in the present invention are known per se, for example from the document US 2005/0141240 A1. However, when applied as a bonding material between LED-chips and optical elements, there is an additional effect that the material exhibits good properties as an adhesive material for obtaining a physical and an optical bond between the LED-chip and the optical element, therefore making it very suitable as a bonding material between LED chips and optical elements.

The curing of the bonding material may heating said at least one assembly at a temperature below about 300° C., preferably at or below 200° C.

The heating in the curing step may be preceded by a step wherein essentially all remaining liquid medium is removed from the bonding material under reduced pressure, such as vacuum.

The metal oxide of the metal oxide nanoparticles may be selected from the group consisting of oxides of Zr, Ti, Hf, Zn, Nb, Ta, B, Si, Al, Ga, Ge, Y, Sn, Pb and combinations thereof, in order to obtain a suitable refractive index of the obtained bond, typically in the range of from 1.45 to 2.1.

The method of the present invention may further comprise removing part of the liquid medium from the bonding material after the bonding material is arranged on said surface, but prior to the placing of the optical element on the LED-chip.

It is advantageous that at least part of the liquid medium of the bonding material is removed before the optical element is placed on the LED-chip. For instance, by removing liquid medium, the bonding material is turned into a tacky, high viscous material, functioning as an adhesive. In addition, there are less amounts of liquid medium to be dried out from the bonding material in the curing step.

The mean particle size of said metal oxide particles may typically be in the range of from about 4 to about 80 nm. By using metal oxide particles in this size range, low temperatures can be used for curing. This helps to form a dense bonding material at low temperatures, which temperatures are not detrimental to the LEDs.

Preferably, the liquid medium in which the metal oxide nanoparticles are dispersed is both a dispersant and a surfactant to the nanoparticles. By choosing a liquid medium that is both a dispersant and a surfactant to the metal oxide nanoparticles, the particles will not flocculate or aggregate when the liquid medium is removed. Examples of such liquid medium include ethylene glycol ethers, such as 2-buthoxy-ethanol and 2-propoxy-ethanol.

In embodiments of the present invention, the optical element placed on the LED chip is of an inorganic material. The bonding material of the invention is very heat resistant. In addition, inorganic optical elements (e.g. of polycrystalline ceramics) are very heat resistant, and thus this material system may be used on high-power LEDs, dissipating high amounts of heat.

In a second aspect, the present invention relates to a light emitting device comprising at least one light emitting diode and an optical element bonded to a light emitting surface of said light emitting diode by means of a bonding material consisting of metal oxide nanoparticles, typically obtainable by the method of the present invention.

In a third aspect, the present invention relates to the use of a stable colloidal sol of metal oxide nanoparticles in a liquid medium as a bonding material to bond an optical element to the light emitting surface of a light emitting diode.

### BRIEF DESCRIPTION OF THE DRAWINGS

This and other aspects of the present invention will now be described in more detail, with reference to the appended drawings showing a currently preferred embodiment of the invention.

FIG. 1 illustrates schematically a light-emitting device according an embodiment of the present invention.

### DETAILED DESCRIPTION OF PREFERRED EMBODIMENTS

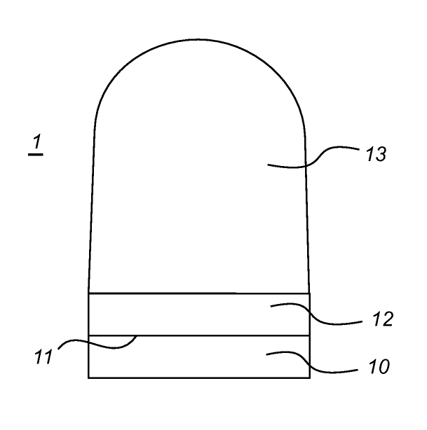

FIG. 1 shows a light-emitting device 1 according to an embodiment of the invention. The light-emitting device 1 may for example be used for illumination purposes. It comprises a light emitting diode (LED) chip 10, which is connected to an optical element 13 by means of a bond 12, such that the bond 12 couples the light emitted by the LED chip 10 from a light-emitting surface 11 of the LED chip to the optical element 13.

The optical element 13 in FIG. 1 is an optical dome for extracting light from the LED-chip. However, the optical element 13 may adopt other forms, for example it may be designed as a plate. The optical element may be of an organic material (for example PMMA), silicone, or of an inorganic material, such as a polycrystalline ceramic material or glass. Preferably, the optical element is of a material that is stable with regards to light of the wavelengths emitted by the underlying LED, and with regards to the temperatures achieved in the device during operation, typically an inorganic material.

The optical element 13 may further comprise additional components, such as luminescent (fluorescent and/or phosphorescent) materials in order to at least partly convert the color of the light emitted by the LED chip 10.

Examples of optical elements suitable for use in the present invention include, but are not limited to light extraction domes, lenses, collimators, and color-converting plates.

The LED-chip 11 is preferably of flip-chip type and mounted on a substrate (not shown).

The bond 12 is at least partially optically transmissive or transparent, whereby upon operation of the light emitting device 1, light emitted by the LED chip 10 is coupled from the light emitting surface 11 thereof, via the bond 12 to the optical element 12, for example for extraction of the generated light.

As used herein, the term “light emitting diode (abbreviated LED)” refers to all types of light emitting diodes known to those skilled in the art, and includes, but is not limited to inorganic based light emitting diodes, organic based light emitting diodes, such as polyLEDs and OLEDs, and also refers to laser diodes. In the context of the present invention, “light” is taken to encompass the wavelength range of from ultra-violet radiation to infrared radiation, especially the visible and near visible range therein.

The device of the present application is especially suited for, but not limited to, use with high power LEDs, for example such LEDs that reach temperatures of 185° C. and above during operation. Further, so-called flip-chip LEDs, having both the cathode and the anode on the same side of the light-emitting surface, are especially contemplated for use in the present invention.

Further, LEDs having an inorganic light-emitting surface, such as a mono-crystalline surface, for example of sapphire, are especially contemplated for use in the present invention.

According to the present invention, the bond 12 is an inorganic material of metal oxide nanoparticles, in particular a dense layer derived from a stable colloidal sol of metal oxide nanoparticles, typically wherein the metal is Zr, Ti, Hf, Zn, Nb, Ta, B, Si, Al, Ga, Ge, Y, Sn or Pb, for example ZrO₂ or TiO₂, and combinations and mixtures thereof. A method to obtain such a bond will be described herein below, but in summary, a colloidal sol of metal oxide nanoparticles is dried and heated in order to form the dense layer.

The bond exhibits high photo and thermal stability (the working temperature for a LED chip can very well exceed 100° C.). As a result, high-power and high lumen LED-chips can be employed whereby high-brightness light emitting devices can be realized.

A bond of this material typically has a refractive index in the range of from about 1.45 to about 2.1, preferably 1.6 to 1.9, in order to minimize internal reflection in the interface from the light emitting surface 11 of the LED chip 10 to the bond 12 and in the interface from the bond 12 to the optical element 13.

A method for the manufacture of a light-emitting device, such as the device 1 in FIG. 1 will now be described.

First, a bonding material is prepared. The bonding material is a colloidal sol of inorganic metal oxide nanoparticles dispersed in a liquid medium, which is stabilized against flocculation and/or agglomeration.

The metal oxide is typically an oxide of one or more metals selected from the group consisting of Zr, Ti, Hf, Zn, Nb, Ta, B, Si, Al, Ga, Ge, Y, Sn and Pb. The metal oxide particles may be of a single oxide or of combinations or mixtures of different oxides. Preferably, a high refractive index oxide is used, such as ZrO₂ or TiO₂, single component, or in combinations, such as ZrO₂—TiO₂, ZrO₂—SiO₂, TiO₂—SiO₂, ZrO₂—SiO₂—B₂O₃, TiO₂—SiO₂—B₂O₃, ZrO₂—TiO₂—SiO₂ or ZrO₂—TiO₂—SiO₂—B₂O₃.

In preferred embodiments, the metal oxide is ZrO₂ or TiO₂, due to the high refractive index obtainable for bonds based on these oxides.

The sol may be prepared in any suitable manner known to those skilled in the art.

Typically, the median particle size of the metal oxide nanoparticles is in the range of from about 4 to about 80 nm, such as for example from about 4 to about 30 nm.

The concentration of the metal oxide nanoparticles in the colloidal sol typically is in the range of from 20 to 30% by weight, based on the total weight of the sol. A stable liquid sol may also be formed at both lower and higher concentrations, and such sols may be used in the present invention. However, for the purpose of the invention, the concentration of metal oxide nanoparticles should preferably be optimized to yield a viscous sol, as viscous as possible, but still one that flows enough to be homogeneously dispersed. Depending on particles size, concentrations between 20 and 30% by weight are thus appropriate for deposition as bonding layer.

The liquid medium is preferably one that acts both as a dispersant and as a surfactant for the metal oxide particles. As a result, the liquid sol can be concentrated, for example by removal (e.g. evaporation) of the liquid medium, without any substantial flocculation or agglomeration of the metal oxide nanoparticles.

Examples of such a liquid medium includes ethylene glycol ethers, preferably 2-buthoxy ethanol or 2-propoxyethanol, or mixtures of ethylene glycol ethers, in that case preferably comprising 2-buthoxy ethanol or 2-propoxyethanol.

The sols contemplated in the present invention, only comprising inorganic metal oxide nanoparticles dispersed in a liquid medium, is much less reactive towards condensation reactions than a sol-gel that contains reactive matrix formers, such as zirconium or titanium alkoxides, thus the shelf life is high.

The bonding material in the form of a liquid sol is then arranged on a light emitting surface of a LED-chip (a surface of the LED chip through which light exits the LED-chip), on a surface of a optical element, which surface is adapted to face the light emitting surface of the LED-chip, or on both.

Suitable methods of arranging the bonding material on the surface(s) include, but are not limited to, dispensing, spray coating and spin coating, dip coating, doctor blade coating and other coating methods known to those skilled in the art.

When the bonding material is arranged on the surface(s), at least part of the liquid medium is optionally removed from the sol, such a by evaporation in reduced pressure and/or by application of heat. Preferably, the optical element is placed on the LED-chip at a state of the bonding material when there is as high solid content as possible, but the material is still deformable. This allows for compensation of any non-flatness on of the parts to be bonded. Typically, at solid concentrations ranging from 30-50 wt. %, when the sol has turned into a tacky, viscous sol, the optical element is picked and placed on the LED chip with the bonding material there between, optionally but not necessarily while being compressed and heated (thermo compression), to form a LED-optics assembly.

Thereafter, essentially all remaining liquid medium is removed from the bonding material by drying, typically at reduced pressure and at moderate temperatures, where condensation of the metal oxide is slow, and the bonding material subsequently is cured by heat treatment. Depending on the duration of the drying process, the temperature of the curing may be below about 300° C., preferably at or below about 200° C., which is enough to obtain the desired properties in terms of mechanical strength and appropriate value of refractive index, in order to match it with the refractive index of the LED chip and the optical element.

During the drying and curing of the sol, a self-arranged densely packed oxide layer of nanoparticles is obtained, even at temperatures not detrimental to the LED-chip The formed dense inorganic oxide layer is thermally stable.

During the release of the liquid medium, the solid content in the bonding material layer increases, the layer shrinks and the nanoparticles self-arrange into a packed layer. By tuning the particles size distribution of oxide nanoparticles dispersed in the colloidal sol, higher packing density, which implies lower porosity, can be obtained. Consequently, the refractive index and optical transmission are enhanced.

The person skilled in the art realizes that the present invention by no means is limited to the preferred embodiments described above. On the contrary, many modifications and variations are possible within the scope of the appended claims. For example, even though one LED chip is shown in FIG. 1, a plurality of LED chips may be bonded to one optical element to form a multi LED assembly.

1. A method for the production of a light-emitting device, the method comprising:
(a) providing at least one light-emitting diode and at least one optical element;
(b) arranging a bonding material, comprising a stable colloidal sol of inorganic nanoparticles of metal oxide or oxide of B or Si, having a mean particle size ranging from about 4 nm to about 80 nm, dispersed in a liquid medium, on a light-emitting surface of said at least one light emitting diode and/or on a surface of said at least one optical element;
(c) placing said at least one optical element on the light emitting surface of said at least one light emitting diode having said bonding material therebetween to form at least one assembly; and
(d) curing said bonding material by heating to form an inorganic bond.

2. A method according to claim 1, wherein said curing comprises heating said at least one assembly at a temperature below 300° C.

3. A method according to claim 1, wherein said curing step (d) comprises:
(d1) removing at least part of said liquid medium is performed under reduced pressure; and
(d2) heating said at least one assembly at a temperature below 300° C.

4. A method according to claim 1, wherein said metal oxide is selected from the group consisting of: oxides of Zr, Ti, Hf, Zn, Nb, Ta, Al, Ga, Ge, Y, Sn, Pb and combinations thereof.

5. A method according to claim 1, wherein the concentration of said metal oxide in said stable colloidal sol ranges from about 20% to about 30% by weight.

6. A method according to claim 1, wherein step (b) further comprises, after the bonding material is arranged on said surface:
(b2) removing part of said liquid medium to increase the viscosity of said bonding material.

7. (canceled)

8. A method according to claim 1, wherein said liquid medium comprises at least one of a dispersant and a surfactant to said metal oxide nanoparticles.

9. A method according to claim 1, wherein said liquid medium comprises at least one ethylene glycol ether.

10. A method according to claim 1, wherein said optical element comprises an inorganic material.

11. A method according to claim 1, wherein said bonding material, after curing, has a refractive index in the range of from about 1.45 to about 2.1.

12. A light-emitting device comprising at least one light emitting diode having a light-emitting surface and an optical element bonded to said light-emitting surface by means of a bonding material, comprising a plurality of nanoparticles of metal oxide or oxide of B or Si, having a mean particle size ranging from about 4 nm to about 80 nm.

13-14. (canceled)
